(19) United States
(12) Patent Application Publication
(10) Pub. No.: US 2025/0309102 A1
(43) Pub. Date: Oct. 2, 2025

(54) METHOD FOR MANUFACTURING ELECTRONIC DEVICE AND ELECTRONIC DEVICE PREPARED BY USING THE SAME

(71) Applicant: InnoLux Corporation, Miao-Li County (TW)

(72) Inventors: Yu-Ting TSAI, Miao-Li County (TW); Wei-Ju LIAO, Miao-Li County (TW); Yu-Tsung LIU, Miao-Li County (TW); I-An YAO, Miao-Li County (TW)

(21) Appl. No.: 19/065,474

(22) Filed: Feb. 27, 2025

Related U.S. Application Data
(60) Provisional application No. 63/570,996, filed on Mar. 28, 2024.

(30) Foreign Application Priority Data
Sep. 23, 2024 (CN) 202411323771.4

(51) Int. Cl. H01L 23/522; H01L 21/768; H01L 23/532; H05K 1/02

(52) U.S. Cl. CPC H01L 23/5226; H01L 21/76885; H01L 21/76892; H01L 23/53219; H01L 23/53261; H05K 1/0296

(57) ABSTRACT

A method for manufacturing an electronic device includes the following steps: providing a substrate; forming a first conductive layer on the substrate; patterning the first conductive layer to form a first conductive pattern; forming a second conductive layer on the first conductive pattern; and patterning the second conductive layer to form a second conductive pattern, wherein the second conductive pattern includes a first sub-pattern and a second sub-pattern, and the first sub-pattern is disposed on the first conductive pattern, wherein a distance between the first conductive pattern and the second sub-pattern is less than a distance between the first sub-pattern and the second sub-pattern.

### CROSS-REFERENCE TO RELATED APPLICATIONS

This application claims the benefits of the Chinese Patent Application Serial Number 202411323771.4, filed on Sep. 23, 2024, the subject matter of which is incorporated herein by reference.

This application claims the benefit of filing date of U.S. Provisional Application Ser. No. 63/570,996, filed Mar. 28, 2024 under 35 USC § 119(e)(1).

### BACKGROUND

### Field

The present disclosure relates to a method for manufacturing an electronic device and, more specifically, to a method which can reduce the line width or improve the component density.

### Description of Related Art

Science and technology have developed rapidly in the past half century. Nowadays, people's lives are inseparable from electronic products. As consumers' living habits change, electronic products are developing toward miniaturization, such as being light, thin, short, and small. By miniaturizing components and increasing component density, it is beneficial to be used in miniaturized electronic devices.

However, due to the influence of process limitations such as photolithography and/or etching capabilities, the miniaturization of patterns is limited, resulting in challenges in component miniaturization.

Therefore, it is desirable to provide an electronic device to solve the conventional defects.

### SUMMARY

The present disclosure provides a method for manufacturing an electronic device, comprising the following steps: providing a substrate; forming a first conductive layer on the substrate; patterning the first conductive layer to form a first conductive pattern; forming a second conductive layer on the first conductive pattern; and patterning the second conductive layer to form a second conductive pattern, wherein the second conductive pattern comprises a first sub-pattern and a second sub-pattern, and the first sub-pattern is disposed on the first conductive pattern, wherein a distance between the first conductive pattern and the second sub-pattern is less than a distance between the first sub-pattern and the second sub-pattern.

The present disclosure further provides an electronic device, comprising: a substrate; a first conductive pattern disposed on the substrate; and a second conductive pattern comprising a first sub-pattern and a second sub-pattern, wherein the first sub-pattern is disposed on the first conductive pattern, and the second sub-pattern is disposed on the substrate, wherein a distance between the first conductive pattern and the second sub-pattern is less than a distance between the first sub-pattern and the second sub-pattern.

Other novel features of the disclosure will become more apparent from the following detailed description when taken in conjunction with the accompanying drawings.

### BRIEF DESCRIPTION OF DRAWINGS

FIG. 1A and FIG. 1B are schematic views showing a process of a method for manufacturing a part of an electronic device according to one embodiment of the present disclosure.

FIG. 2A, FIG. 2B-1 and FIG. 2B-2 are schematic views showing a process of a method for manufacturing a part of an electronic device according to one embodiment of the present disclosure.

FIG. 3A to FIG. 3F are schematic views showing a process of a method for manufacturing a part of an electronic device according to one embodiment of the present disclosure.

FIG. 4 is a schematic view showing a part of an electronic device according to one embodiment of the present disclosure.

FIG. 5 is a schematic view showing a part of an electronic device according to one embodiment of the present disclosure.

### DETAILED DESCRIPTION

The following is specific embodiments to illustrate the implementation of the present disclosure. Those who are familiar with this technique can easily understand the other advantages and effects of the present disclosure from the content disclosed in the present specification. The present disclosure can also be implemented or applied by other different specific embodiments, and various details in the present specification can also be modified and changed according to different viewpoints and applications without departing from the spirit of the present disclosure.

It should be noted that, in the present specification, when a component is described to have an element, it means that the component may have one or more of the elements, and it does not mean that the component has only one of the element, except otherwise specified. Furthermore, the ordinals recited in the specification and the claims such as “first”, “second” and so on are intended only to describe the elements claimed and imply or represent neither that the claimed elements have any proceeding ordinals, nor that sequence between one claimed element and another claimed element or between steps of a manufacturing method. The use of these ordinals is merely to differentiate one claimed element having a certain designation from another claimed element having the same designation.

In the specification and the appended claims of the present disclosure, certain words are used to refer to specific elements. Those skilled in the art should understand that electronic device manufacturers may refer to the same components by different names. The present specification does not intend to distinguish between elements that have the same function but have different names. In the following description and claims, words such as “comprising”, “including”, “containing”, and “having” are open-ended words, so they should be interpreted as meaning “containing but not limited to . . . ”. Therefore, when the terms “comprising”, “including”, “containing” and/or “having” are used in the description of the present disclosure, they specify the existence of corresponding features, regions, steps, operations and/or components, but do not exclude the existence of one or more corresponding features, regions, steps, operations and/or components.

The terms, such as “about”, “substantially”, or “approximately”, are generally interpreted as within 10%, 5%, 3%, 2%, 1%, or 0.5% of a given value or range. The quantity given here is an approximate quantity, that is, without specifying “about”, “approximately”, “substantially” and “approximately”, “about”, “approximately”, “substantially” and “approximately” can still be implied. Furthermore, when a value is “in a range from a first value to a second value” or “in a range between a first value and a second value”, the value can be the first value, the second value, or another value between the first value and the second value.

In the present specification, except otherwise specified, the terms (including technical and scientific terms) used herein have the meanings generally known by a person skilled in the art. It should be noted that, except otherwise specified, in the embodiments of the present disclosure, these terms (for example, the terms defined in the generally used dictionary) should have the meanings identical to those known in the art, the background of the present disclosure or the context of the present specification, and should not be read by an ideal or over-formal way.

In addition, relative terms such as “below” or “under” and “on”, “above” or “over” may be used in the embodiments to describe the relative relationship between one element and another element in the drawings. It will be understood that if the device in the drawing was turned upside down, elements described on the “lower” side would then become elements described on the “upper” side. When a unit (for example, a layer or a region) is referred to as being “on” another unit, it can be directly on the another unit or there may be other units therebetween. Furthermore, when a unit is said to be “directly on another unit”, there is no unit therebetween. Moreover, when a unit is said to be “on another unit”, the two have a top-down relationship in a top view, and the unit can be disposed above or below the another unit, and the top-bottom relationship depends on the orientation of the device.

In the present disclosure, the distance, width, length and thickness can be measured by using an optical microscope or a cross-sectional image in an electron microscope, but the present disclosure is not limited thereto. In addition, any two values or directions used for comparison may have certain errors. If the first value is equal to the second value, it implies that there may be an error of about 10% between the first value and the second value. If the first direction is perpendicular to the second direction, the angle between the first direction and the second direction may be between 80° and 100°. If the first direction is parallel to the second direction, the angle between the first direction and the second direction may be between 0° and 10°.

It should be noted that the technical solutions provided in different embodiments below can be replaced, combined or mixed with each other to constitute another embodiment without violating the spirit of the present disclosure.

The electronic device of the present disclosure may include, for example, a display device, a sensing device, an antenna device, a touch device, a tiled device or other suitable electronic devices, but the present disclosure is not limited thereto. The display device of the present disclosure may be a non-self-luminous display device or a self-luminous display device, such as a liquid crystal display, a cholesteric liquid crystal display, an electro-phoretic display, an organic light-emitting diode display, a light emitting diode display, but the present disclosure is not limited thereto. The display device may include light emitting diodes, light conversion layers or other suitable materials, or a combination thereof, but the present disclosure is not limited thereto. The light emitting diode may comprise, for example, an organic light emitting diode (OLED), mini LED, micro LED or quantum dot LED (which may include QLED or QDLED), but the present disclosure is not limited thereto. The light conversion layer may comprise wavelength conversion materials and/or filter materials, and may comprise, for example, fluorescence, phosphors, quantum dots (QDs), other suitable materials or a combination thereof, but the present disclosure is not limited thereto. The sensing device may include, for example, a biosensor, a touch sensor, a fingerprint sensor, a light sensor, an infrared sensor, a temperature sensor, other suitable sensors, or a combination of the above-mentioned types of sensors. The antenna device may, for example, be a liquid crystal antenna or other kind of antenna type, but the present disclosure is not limited thereto. The tiled device may include, for example, a tiled display device or a tiled antenna device, but the present disclosure is not limited thereto. The electronic device may include electronic components, and the electronic components can include passive components, active components or a combination thereof, such as capacitors, resistors, inductors, varactor diodes, variable capacitors, filters, diodes, transistors, sensors, microelectromechanical system components (MEMS), chips, etc., but the present disclosure is not limited thereto. It should be noted that, the electronic device of the present disclosure may be various combination of the aforesaid device, and the present disclosure is not limited thereto.

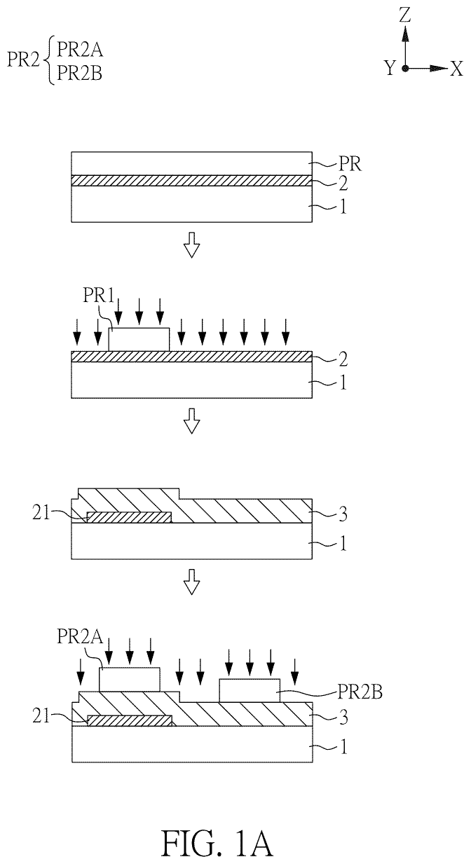

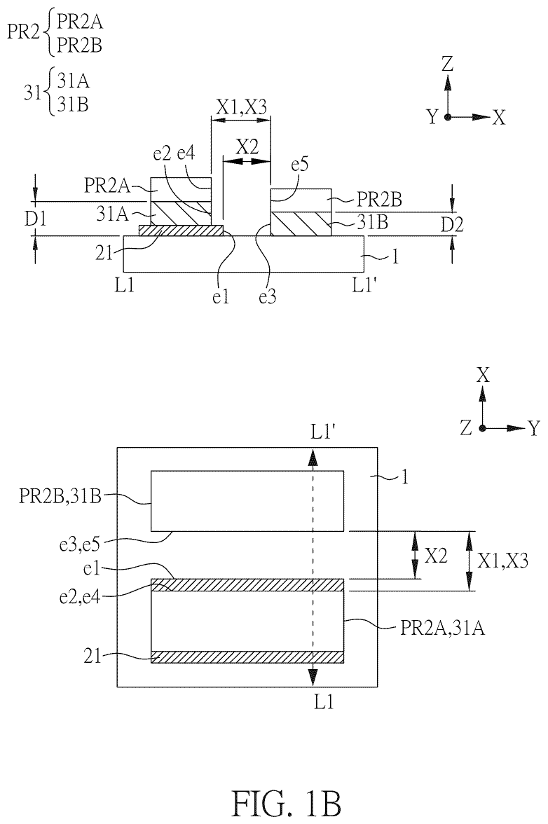

FIG. 1A and FIG. 1B are schematic views showing a process of a method for manufacturing a part of an electronic device according to one embodiment of the present disclosure. The lower half-part of FIG. 1B is a top schematic view of a part of the electronic device, and the upper half-part of FIG. 1B is a cross-sectional schematic view of the line L1-L1′.

In one embodiment of the present disclosure, as shown in FIG. 1A, the method for manufacturing an electronic device comprises the following steps. A substrate 1 is provided, and a first conductive layer 2 is formed on the substrate 1. Next, the first conductive layer 2 is patterned to form a first conductive pattern 21. More specifically, before the step of patterning the first conductive layer 2, the method may further comprise the steps: forming a photoresist layer PR on the first conductive layer 2; and patterning the photoresist layer PR to form a patterned photoresist PR1. By using the patterned photoresist PR1 as a mask, the first conductive layer 2 can be patterned to form the first conductive pattern 21.

Then, the patterned photoresist PR1 is removed, and a second conductive layer 3 is formed on the first conductive pattern 21. Then, as shown in FIG. 1B, the second conductive layer 3 is patterned to form a second conductive pattern 31, wherein the second conductive pattern 31 comprises a first sub-pattern 31A and a second sub-pattern 31B, the first sub-pattern 31A is disposed on the first conductive pattern 21, and there is a distance X1 between the second sub-pattern 31B and the first sub-pattern 31A. More specifically, before the step of patterning the second conductive layer 3, the method may further comprise: forming a photoresist layer on the second conductive layer 3; and patterning the photoresist layer to form a patterned photoresist PR2, as shown in FIG. 1A. After the step of patterning the second conductive layer 3, as shown in FIG. 1B, in a top view direction Z of the substrate 1, the patterned photoresist PR2 and the second conductive pattern 31 are overlapped. By using the patterned photoresist PR2 as a mask, the second conductive layer 3 can be patterned to form the second conductive pattern 31.

In one embodiment of the present disclosure, as shown in FIG. 1A, the patterned photoresist PR2 may comprise a first sub-photoresist pattern PR2A and a second sub-photoresist pattern PR2B. In the top view direction Z of the substrate 1, the first sub-photoresist pattern PR2A and the first conductive pattern 21 are overlapped. After the step of patterning the second conductive layer 3, as shown in FIG. 1B, the first sub-photoresist pattern PR2A and the first sub-pattern 31A are overlapped, and the second sub-photoresist pattern PR2B and the second sub-pattern 31B are overlapped. By using the first sub-photoresist pattern PR2A and the second sub-photoresist pattern PR2B as masks, the second conductive layer 3 can be patterned to form the first sub-pattern 31A and the second sub-pattern 31B. Thus, as shown in FIG. 1B, the edge e2 of the first sub-pattern 31A may be approximately aligned with the edge e4 of the first sub-photoresist pattern PR2A, and the edge e3 of the second sub-pattern 31B may be approximately aligned with the edge e5 of the second sub-photoresist pattern PR2B. Thus, the distance X1 between the first sub-pattern 31A and the second sub-pattern 31B may be approximately equal to the distance X3 between the first sub-photoresist pattern PR2A and the second sub-photoresist pattern PR2B. The “distance X1” refers to, for example, the shortest straight line distance between the edge e2 of the first sub-pattern 31A and the edge e3 of the second sub-pattern 31B observed from the top view direction Z of the substrate 1. The “distance X3” refers to, for example, the shortest straight line distance between the edge e4 of the first sub-photoresist pattern PR2A and the edge e5 of the second sub-photoresist pattern PR2B observed from the top view direction Z of the substrate 1. In one embodiment of the present disclosure, the distance D1 between the first sub-pattern 31A and the substrate 1 is greater than the distance D2 between the second sub-pattern 31B and the substrate 1. The “distance D1” refers to, for example, the distance from the upper surface of the first sub-pattern 31A to the upper surface of the substrate 1 in the top view direction Z of the substrate 1. The “distance D2” refers to, for example, the distance from the upper surface of the second sub-pattern 31B to the upper surface of the substrate 1 in the top view direction Z of the substrate 1.

In one embodiment of the present disclosure, the step of patterning the first conductive layer 2 may further include a step of etching the first conductive layer 2 with a first etching substance. In one embodiment of the present disclosure, the step of patterning the second conductive layer 3 may further comprise a step of etching the second conductive layer 3 with a second etching substance, wherein the same etching substance (for example, the second etching substance) has etching selectivity for the first conductive layer 2 and the second conductive layer 3. Thus, when etching the second conductive layer 3, the first conductive pattern 21 is not easily etched by the second etching substance. Therefore, the distance X2 between the first conductive pattern 21 and the second sub-pattern 31B may be less than the distance X1 between the first sub-pattern 31A and the second sub-pattern 31B, and the distance X2 between the first conductive pattern 21 and the second sub-pattern 31B may be less than the distance X3 between the first sub-photoresist pattern PR2A and the second sub-photoresist pattern PR2B. The second etching substance has different etching rates for the first conductive layer 2 and the second conductive layer 3, which can achieve the effect of reducing the line width or increasing the component density. More specifically, for example, when the distance X3 between the first sub-photoresist pattern PR2A and the second sub-photoresist pattern PR2B is the process limit, since the first conductive pattern 21 is not easily etched by the second etching substance, the distance between components or conductive lines is not limited to the distance X3 between the first sub-photoresist pattern PR2A and the second sub-photoresist pattern PR2B. In other words, the effect of reducing the line width or increasing the component density can be achieved. The “distance X2” refers to, for example, the shortest straight line distance between the edge e1 of the first conductive pattern 21 and the edge e3 of the second sub-pattern 31B observed from the top view direction Z of the substrate 1. The “distance X1” refers to, for example, the shortest straight line distance between the edge e2 of the first sub-pattern 31A and the edge e3 of the second sub-pattern 31B observed from the top view direction Z of the substrate 1.

In the present disclosure, the methods for forming the first conductive layer 2, the second conductive layer 3 and the photoresist layer PR may respectively comprise chemical vapor deposition, physical vapor deposition, sputtering, electroplating, chemical plating, coating or a combination thereof, but the present disclosure is not limited thereto. Suitable coating methods may include dip coating, spin coating, roller coating, blade coating, and spray coating or a combination thereof, but the present disclosure is not limited thereto. Patterning may be performed using any suitable method, such as a photolithography and an etching method, wherein the etching method may include dry etching, wet etching, or a combination thereof, but the present disclosure is not limited thereto. The present disclosure can achieve the effect of reducing the line width or increasing the component density through multiple photolithography and etching processes, thereby reducing the size of components and applying to the manufacturing process of micro components. In the present disclosure, a suitable method may be used to remove the photoresist, such as stripping with force, but the present disclosure is not limited thereto.

In the present disclosure, the substrate 1 may be a rigid substrate or a flexible substrate, and suitable materials may comprise glass, quartz, sapphire, ceramics, plastics, polycarbonate (PC), polyimide (PI), polypropylene (PP), polyethylene terephthalate (PET), polymethylmethacrylate (PMMA), other suitable material or a combination thereof, but the present disclosure is not limited thereto. In the present disclosure, the material of the first conductive layer 2 may comprise indium tin oxide (ITO), molybdenum, molybdenum nitride (MoN), tungsten-molybdenum alloy (MoW), tungsten or a combination thereof, but the present disclosure is not limited thereto. In the present disclosure, the material of the second conductive layer 3 may comprises titanium nitride (TiN), titanium aluminum alloy (TiAl), titanium aluminum nitride (TiAlN), titanium aluminum oxide (TiAlO), titanium silicon aluminum (TiSiAl), titanium tungsten alloy (TiW), titanium tungsten nitride (TiWN), aluminum nitride (AlNx) or a combination thereof, but the present disclosure is not limited thereto. In the present disclosure, the first etching substance is different from the second etching substance, for example, the first etching substance may comprise oxalic acid (H₂C₂O₄), nitric acid (HNO₃) or a combination thereof, the second etching substance may comprise sulfur hexafluoride (SF₆), carbon tetrafluoride (CF₄), boron trichloride (BCl₃), chlorine (Cl₂) or a combination thereof, but the present disclosure is not limited thereto.

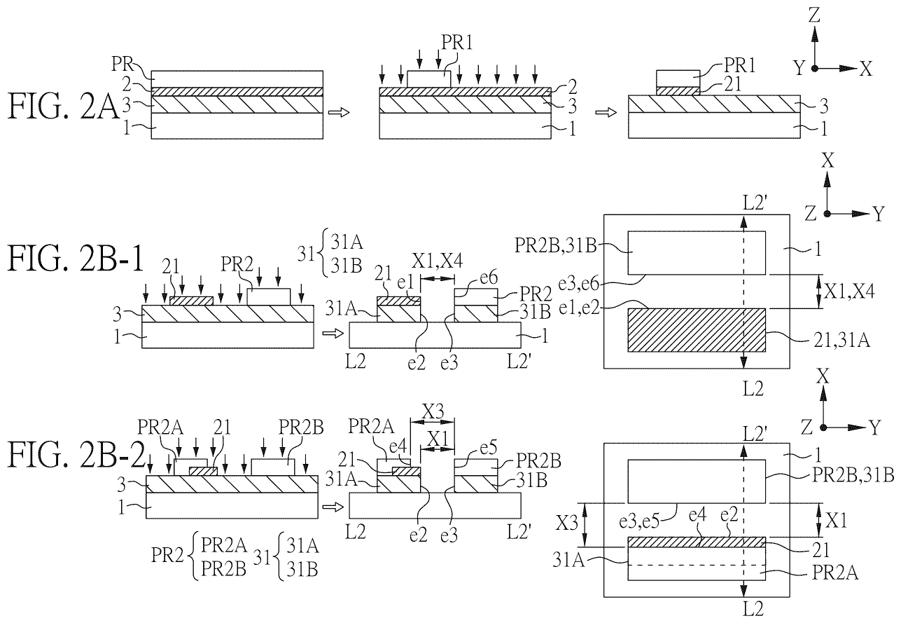

FIG. 2A, FIG. 2B-1 and FIG. 2B-2 are schematic views showing a process of a method for manufacturing a part of an electronic device according to one embodiment of the present disclosure. The rightmost picture of FIG. 2B-1 and FIG. 2B-2 are top schematic views of a part of the electronic device, and the middle picture of FIG. 2B-1 and FIG. 2B-2 are cross-sectional schematic views of the line L2-L2′.

In one embodiment of the present disclosure, the method for manufacturing the electronic device may comprise: providing a substrate 1; forming a second conductive layer 3 on the substrate 1; and forming a first conductive layer 2 on the second conductive layer 3. Next, the first conductive layer 2 is patterned to form the first conductive pattern 21. More specifically, before the step of patterning the first conductive layer 2, the method may further comprise: forming a photoresist layer PR on the first conductive layer 2; and patterning the photoresist layer PR to form a patterned photoresist PR1. By using the patterned photoresist PR1 as a mask, the first conductive layer 2 can be patterned to form the first conductive pattern 21. Then, the patterned photoresist PR1 is removed.

In the present disclosure, after the steps shown in FIG. 2A, the steps shown in FIG. 2B-1 or FIG. 2B-2 may be performed. In one embodiment of the present disclosure, as shown in FIG. 2B-1, after patterning the first conductive layer 2, the second conductive layer 3 is patterned to form the second conductive pattern 31, wherein the second conductive pattern 31 comprises a first sub-pattern 31A and a second sub-pattern 31B, the first conductive pattern 21 is disposed on the first sub-pattern 31A, and there is a distance X1 between the second sub-pattern 31B and the first sub-pattern 31A. More specifically, before the step of patterning the second conductive layer 3, the method may further comprise: forming a photoresist layer on the second conductive layer 3; and patterning the photoresist layer to form a patterned photoresist PR2, as shown in FIG. 2B-1, wherein there is a distance X4 between the patterned photoresist PR2 and the first conductive pattern 21. After the step of patterning the second conductive layer 3, in the top view direction Z of the substrate 1, the first conductive pattern 21 and the first sub-pattern 31A are overlapped, and the patterned photoresist PR2 and the second sub-pattern 31B are overlapped. By using the first conductive pattern 21 and the patterned photoresist PR2 as a mask, the second conductive layer 3 can be patterned to form the first sub-pattern 31A and the second sub-pattern 31B of the second conductive pattern 31. In one embodiment of the present disclosure, the distance X4 between the patterned photoresist PR2 and the first conductive pattern 21 is approximately equal to the distance X1 between the first sub-pattern 31A and the second sub-pattern 31B, but the present disclosure is not limited thereto. The “distance X1” refers to, for example, the shortest straight line distance between the edge e2 of the first sub-pattern 31A and edge e3 of the second sub-pattern 31B observed from the top view direction Z of the substrate 1. The “distance X4” refers to, for example, the shortest straight line distance between the edge e6 of the patterned photoresist PR2 and the edge e1 of the first conductive pattern 21 observed from the top view direction Z of the substrate 1.

In one embodiment of the present disclosure, as shown in FIG. 2B-2, after patterning the first conductive layer 2, the second conductive layer 3 is patterned to form the second conductive pattern 31, wherein the second conductive pattern 31 comprises a first sub-pattern 31A and a second sub-pattern 31B, the first conductive pattern 21 is disposed on the first sub-pattern 31A, and there is a distance X1 between the second sub-pattern 31B and the first sub-pattern 31A. More specifically, before the step of patterning the second conductive layer 3, the method may comprise: forming a photoresist layer on the first conductive pattern 21 and the second conductive layer 3; and patterning the photoresist layer to form a patterned photoresist PR2, as shown in FIG. 2B-2. The patterned photoresist PR2 may comprise a first sub-photoresist pattern PR2A and a second sub-photoresist pattern PR2B, and the first sub-photoresist pattern PR2A and the first conductive pattern 21 may be partially overlapped in the top view direction Z of the substrate 1. After the step of patterning the second conductive layer 3, the first sub-photoresist pattern PR2A and a part of the first sub-pattern 31A are overlapped, and the second sub-photoresist pattern PR2B and the second sub-pattern 31B are overlapped. By using the first sub-photoresist pattern PR2A and the first conductive pattern 21 together as a mask, the second conductive layer 3 is patterned to form the first sub-pattern 31A of the second conductive pattern 31. By using the second sub-photoresist pattern PR2B as a mask, the second conductive layer 3 is patterned to form the second sub-pattern 31B of the second conductive pattern 31. In one embodiment of the present disclosure, the distance X1 between the first sub-pattern 31A and the second sub-pattern 31B may be less than the distance X3 between the first sub-photoresist pattern PR2A and the second sub-photoresist pattern PR2B. The “distance X” refers to, for example, the shortest straight line distance between the edge e2 of the first sub-pattern 31A and the edge e3 of the second sub-pattern 31B observed from the top view direction Z of the substrate 1. The “distance X3” refers to, for example, the shortest straight line distance between the edge e4 of the first sub-photoresist pattern PR2A and the edge e5 of the second sub-photoresist pattern PR2B observed from the top view direction Z of the substrate 1.

In one embodiment of the present disclosure, the step of patterning the first conductive layer 2 may comprise: etching the first conductive layer 2 with a first etching substance. In one embodiment of the present disclosure, the step of patterning the second conductive layer 3 may comprise: etching the second conductive layer 3 with a second etching substance. The same etching substance (for example, the second etching substance) has the etching selectivity for the first conductive layer 2 and the second conductive layer 3. Thus, when etching the second conductive layer 3, the first conductive pattern 21 is not easily etched by the second etching substance. In the present disclosure, by using the first conductive pattern 21 as a mask, the effect of reducing the line width or increasing the component density can be achieved. More specifically, for example, when the distance X3 between the first sub-photoresist pattern PR2A and the second sub-photoresist pattern PR2B is the process limit, the first conductive pattern 21 can be used as a mask, so the distance X1 between the first sub-pattern 31A and the second sub-pattern 31B is not limited to the distance X3 between the first sub-photoresist pattern PR2A and the second sub-photoresist pattern PR2B. Therefore, the effect of reducing the distance between components or conductive lines can be achieved.

In the present disclosure, the methods for forming the first conductive layer 2, the second conductive layer 3 and the photoresist layer PR may be respectively as described above, and are not described again here. Any suitable method may be used to perform the patterning and remove the photoresist, and suitable method can be respectively as described above, and are not described again here. In addition, in the present disclosure, the material of the substrate 1, the first conductive layer 2 and the second conductive layer 3 may be respectively as described above, and are not described again here. In the present disclosure, the first etching substance is different from the second etching substance, and the first etching substance and the second etching substance may be respectively as described above, and are not described again here.

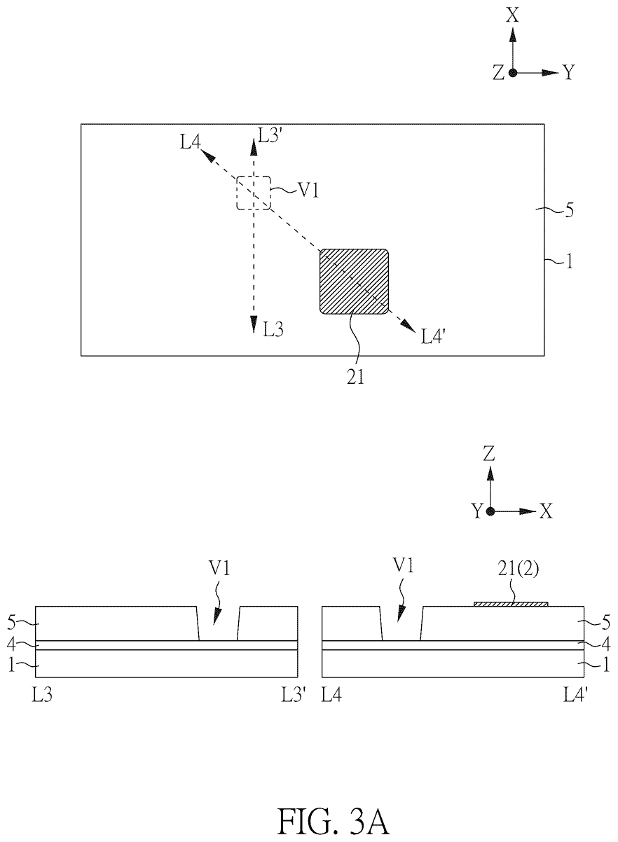

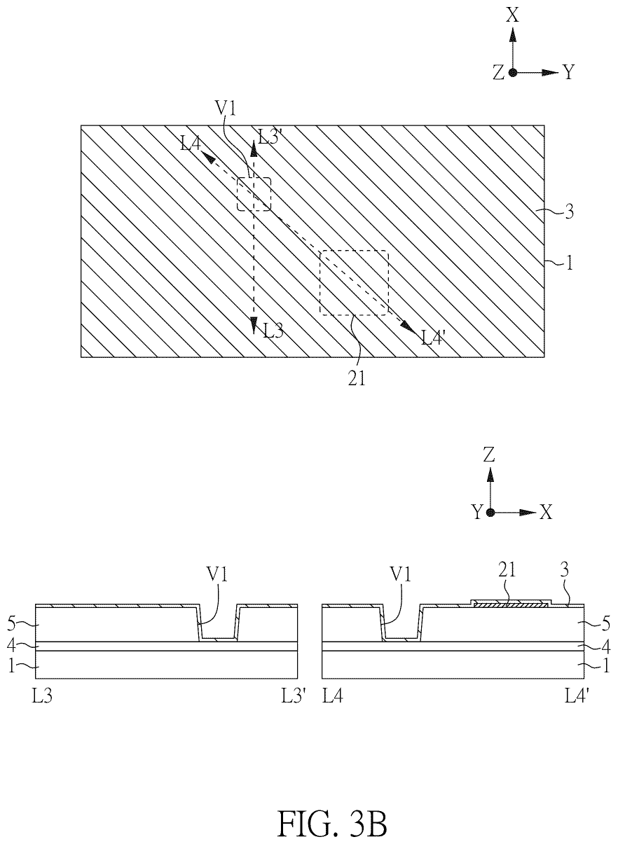

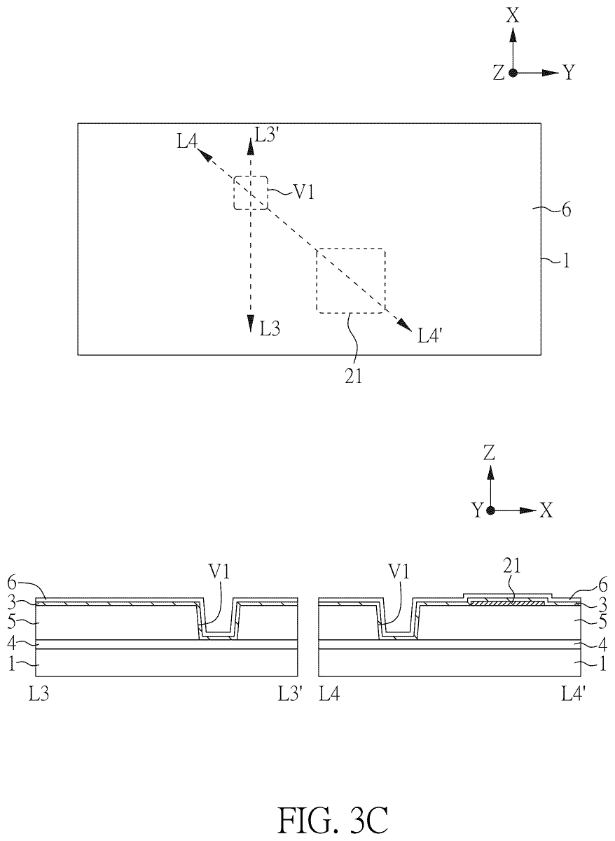

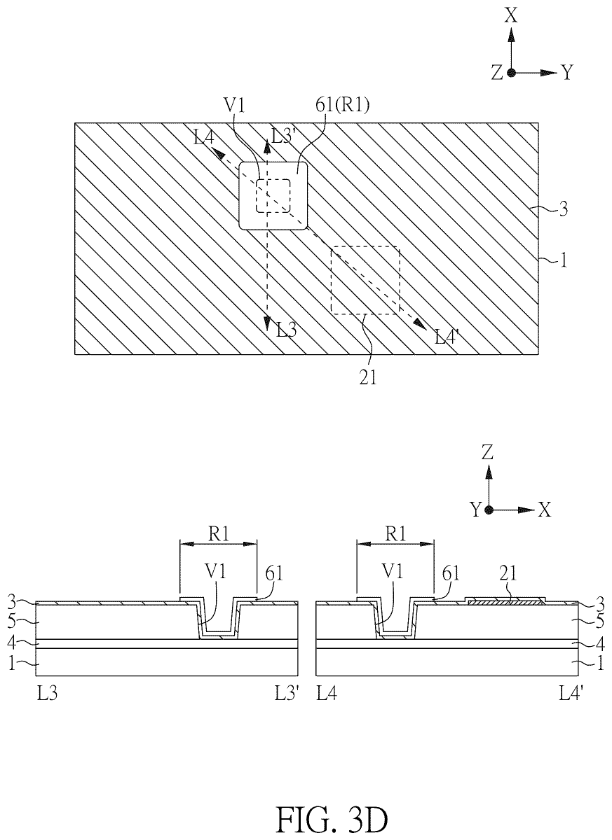

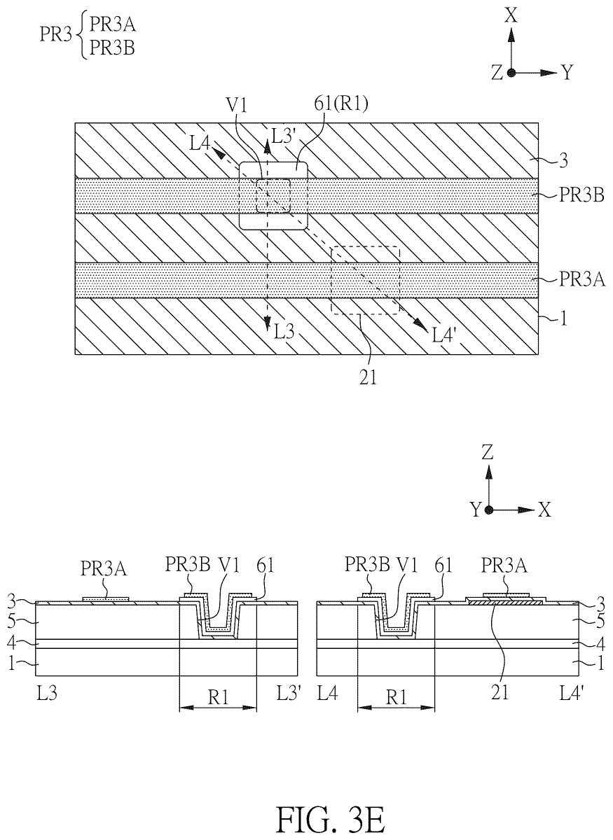

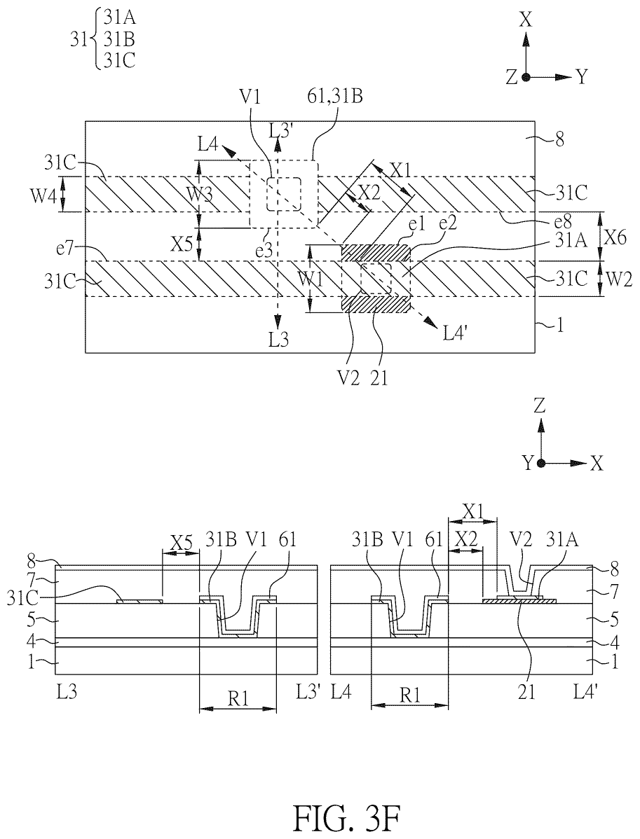

FIG. 3A to FIG. 3F are schematic views showing a process of a method for manufacturing a part of an electronic device according to one embodiment of the present disclosure. The upper parts of FIG. 3A to FIG. 3F are top schematic views, and the lower parts are cross-sectional schematic views of the line L3-L3′ and the line L4-L4′. Herein, the manufacturing method of FIG. 3A to FIG. 3F is similar to that shown in FIG. 1A and FIG. 1B, except for the following differences. In addition, for convenience of explanation, some components are omitted from the figures.

In one embodiment of the present disclosure, even not shown in the figure, a plurality of insulating layers, a semiconductor layer, a conductive layer, other suitable layer or film or a combination thereof may be included between the substrate 1 and the first conductive pattern 21, but the present disclosure is not limited thereto. For example, as shown in FIG. 3A, a third conductive layer 4 and a first insulating layer 5 may be included between the substrate 1 and the first conductive pattern 21. Thus, the method may comprise: forming a third conductive layer 4 on the substrate 1; and forming a first insulating layer 5 on the third conductive layer 4, wherein the first insulating layer 5 comprises a first via V1, and the first via V1 exposes a part of the third conductive layer 4. Next, a first conductive layer 2 is formed on the first insulating layer 5. Then, the first conductive layer 2 is patterned to form a first conductive pattern 21. In one embodiment of the present disclosure, the first conductive pattern 21 and the first via V1 are not overlapped in the top view direction Z of the substrate 1. In one embodiment of the present disclosure, the shape of the first conductive pattern 21 in the top view direction Z of the substrate 1 is not particularly limited, and may be, for example, circle, oval, rectangle or rectangle with curved corners, but the present disclosure is not limited thereto.

Then, as shown in FIG. 3B, a second conductive layer 3 is formed on the first conductive pattern 21 and in the first via V1. Then, as shown in FIG. 3C and FIG. 3D, an etching barrier layer 6 is formed on the second conductive layer 3; and the etching barrier layer 6 is patterned to form a mask 61, wherein the mask 61 and a portion R1 of the second conductive layer 3 are overlapped in the top view direction Z of the substrate 1. In one embodiment of the present disclosure, a part of the mask 61 and the first via V1 are overlapped in the top view direction Z of the substrate 1.

Next, as shown in FIG. 3E, a photoresist layer is formed on the second conductive layer 3 and the mask 61; and the photoresist layer is patterned to form a patterned photoresist PR3. The patterned photoresist PR3 may comprise a first sub-photoresist pattern PR3A and a second sub-photoresist pattern PR3B, and in the top view direction Z of the substrate 1, the first sub-photoresist pattern PR3A and the first conductive pattern 21 may be partially overlapped, and the second sub-photoresist pattern PR3B may be partially overlapped with the first via V1 and the mask 61.

Next, by using the first sub-photoresist pattern PR3A, the second sub-photoresist pattern PR3B and the mask 61 together as a mask, the second conductive layer 3 is patterned to form a second conductive pattern 31. Then, the patterned photoresist PR3 is removed. As shown in FIG. 3F, the second conductive pattern 31 comprises a first sub-pattern 31A, a second sub-pattern 31B and a third sub-pattern 31C, the first sub-pattern 31A is disposed on the first conductive pattern 21, the mask 61 is disposed on the second sub-pattern 31B, the third sub-pattern 31C and the second sub-pattern 31B are adjacent, and the second sub-pattern 31B corresponds to a portion R1 of the second conductive layer 3. More specifically, in the top view direction Z of the substrate 1, the region of the second conductive pattern 31 overlapped with the first conductive pattern 21 is the first sub-pattern 31A, the region of the second conductive pattern 31 overlapped with the mask 61 is the second sub-pattern 31B, the region of the second conductive pattern 31 overlapped with the patterned photoresist PR3 (as shown in FIG. 3E) and outside the first sub-pattern 31A and the second sub-pattern 31B is the third sub-pattern 31C. In one embodiment of the present disclosure, a part of the third sub-pattern 31C may be connected to the first sub-pattern 31A. For example, as shown in FIG. 3F, two third sub-patterns 31C respectively connecting to the first sub-pattern 31A are used as an example. In other words, the first sub-pattern 31A is disposed between two third sub-patterns 31C, but the present disclosure is not limited thereto, and the number and the position of the third sub-pattern 31C may be adjusted according to the needs. For example, in one embodiment, the first sub-pattern 31A may be connected to one third sub-pattern 31C and disposed at one side of the third sub-pattern 31C. In one embodiment of the present disclosure, a part of the third sub-pattern 31C and the second sub-pattern 31B may be connected. For example, as shown in FIG. 3F, two third sub-patterns 31C respectively connected to the second sub-pattern 31B are used as an example; in other words, the second sub-pattern 31B is disposed between two third sub-patterns 31C, but the present disclosure is not limited thereto, and the number and the position of the third sub-pattern 31C may be adjusted according to the needs. For example, in one embodiment, the second sub-pattern 31B may be connected to one third sub-pattern 31C and disposed at one side of the third sub-pattern 31C. In addition, in another embodiment of the present disclosure (not shown in the figure), the second sub-pattern 31B and the first sub-pattern 31A may be respectively disposed at two ends of one third sub-pattern 31C. In one embodiment of the present disclosure, the third sub-pattern 31C may extend along one direction (for example, the Y direction). In the top view direction Z of the substrate 1, the third sub-pattern 31C may be straight type, curve type, repeating S type, Z type or a combination thereof. In one embodiment of the present disclosure, plural third sub-patterns 31C may be parallel to each other or not. In one embodiment of the present disclosure, when observing from the top view direction Z, the maximum width W1 of the first conductive pattern 21 along a direction (for example, the X direction) may be greater than the maximum width W2 of the third sub-pattern 31C connecting to the first sub-pattern 31A along the direction (for example, the X direction). In one embodiment of the present disclosure, when observing the top view direction Z, the maximum width W3 of the mask 61 along a direction (for example, the X direction) may be greater than the maximum width W4 of the third sub-pattern 31C connecting to the second sub-pattern 31B along the direction (for example, the X direction).

In one embodiment of the present disclosure, the distance X2 between the first conductive pattern 21 and the second sub-pattern 31B is less than the distance X1 between the first sub-pattern 31A and the second sub-pattern 31B. In one embodiment of the present disclosure, the distance X5 between the third sub-pattern 31C and the second sub-pattern 31B is less than the distance X1 between the first sub-pattern 31A and the second sub-pattern 31B. The “distance X2” refers to, for example, the shortest straight line distance between the edge e1 of the first conductive pattern 21 and the edge e3 of the second sub-pattern 31B observing from the top view direction Z of the substrate 1. The “distance X” refers to, for example, the shortest straight line distance between the edge e2 of the first sub-pattern 31A and the edge e3 of the second sub-pattern 31B based on the extension direction of the distance X2 when observing from the top view direction Z of the substrate 1. The “distance X5” refers to, for example, the shortest straight line distance from the edge e7 of the third sub-pattern 31C adjacent to and not connecting to the second sub-pattern 31B to the edge e3 of the second sub-pattern 31B observing from the top view direction Z of the substrate 1. In one embodiment of the present disclosure, the distance X6 between two adjacent third sub-patterns 31C is greater than the distance X5 between the second sub-pattern 31B and the third sub-pattern 31C adjacent to and not connected to the second sub-pattern 31B. The “distance X6” refers to, for example, the shortest straight line distance between the edge e7 and the edge e8 of two adjacent third sub-patterns 31C when observed from the top view direction Z of the substrate 1.

In one embodiment of the present disclosure, plural insulating layers, a semiconductor layer, a conductive layer, other suitable layer or film or a combination thereof may be selectively disposed on the second conductive pattern 31 and the mask 61, but the present disclosure is not limited thereto. For example, as shown in FIG. 3F, a second insulating layer 7 and a fourth conductive layer 8 may be further disposed on the second conductive pattern 31 and the mask 61. Thus, the manufacturing method may further comprise: forming a second insulating layer 7 on the mask 61 and the second conductive pattern 31, wherein the second insulating layer 7 comprises a second via V2, and the second via V2 exposes a part of the first sub-pattern 31A. Then, a fourth conductive layer 8 is disposed on the second insulating layer 7 and in the second via V2, and the fourth conductive layer 8 may be electrically connected to the first sub-pattern 31A through the second via V2. In another embodiment of the present disclosure, even not shown in the figure, the second via V2 may expose the first sub-pattern 31A and a part of the first conductive pattern 21 at the same time, but the present disclosure is not limited thereto.

In one embodiment of the present disclosure, the step of patterning the first conductive layer 2 may comprise etching the first conductive layer 2 with a first etching substance. In one embodiment of the present disclosure, the step of patterning the second conductive layer 3 may comprise etching the second conductive layer 3 with a second etching substance, wherein the same etching substance (for example, the second etching substance) has the etching selectivity for the first conductive layer 2 and the second conductive layer 3. Thus, when etching the second conductive layer 3, the first conductive pattern 21 is not easily etched by the second etching substance, so the distance X2 between the first conductive pattern 21 and the second sub-pattern 31B may be less than the distance X1 between the first sub-pattern 31A and the second sub-pattern 31B. In addition, the same etching substance (for example, the second etching substance) has the etching selectivity for the second conductive layer 3 and the mask 61. Thus, when etching the second conductive layer 3, the mask 61 may be used as a mask to achieve the effect of reducing the line width or increasing the component density.

In the present disclosure, the methods for forming the first conductive layer 2, the second conductive layer 3 and the photoresist layer may be as described above, and are not described again here. The methods for forming the third conductive layer 4, the fourth conductive layer 8, the first insulating layer 5 and the second insulating layer 7 may be respectively similar to the method for forming the first conductive layer 2, and are not described again here. Any suitable method may be used to perform patterning and removing the photoresist, and suitable methods may be as described above and are not described again here. In the present disclosure, the first via V1 and the second via V2 may be respectively formed by, for example, mechanical drilling, laser drilling, lithography or a combination thereof, but the present disclosure is not limited thereto.

In the present disclosure, the materials of the substrate 1, the first conductive layer 2 and the second conductive layer 3 may be respectively as described above, and are not described again here. In the present disclosure, the materials of the third conductive layer 4 and the fourth conductive layer 8 may respectively comprise metal, metal oxide, an alloy thereof, or a combination thereof, and for example, may comprise gold, silver, copper, palladium, platinum, ruthenium, aluminum, cobalt, nickel, titanium, molybdenum, manganese, indium zinc oxide (IZO), indium tin oxide (ITO), indium tin zinc oxide (ITZO), indium gallium zinc oxide (IGZO), aluminum zinc oxide (AZO) or a combination thereof, but the present disclosure is not limited thereto. In the present disclosure, the materials of the first insulating layer 5 and the second insulating layer 7 may respectively comprise silicon nitride, silicon oxide, silicon oxynitride, silicon carbonitride or a combination thereof, but the present disclosure is not limited thereto. In the present disclosure, the material of the etching barrier layer 6 may comprise indium tin oxide (ITO), molybdenum, molybdenum nitride (MoN), tungsten-molybdenum alloy (MoW), tungsten or a combination thereof, but the present disclosure is not limited thereto. In the present disclosure, the first etching substance is different from the second etching substance, and the first etching substance and the second etching substance may be respectively as described above and are not described again here.

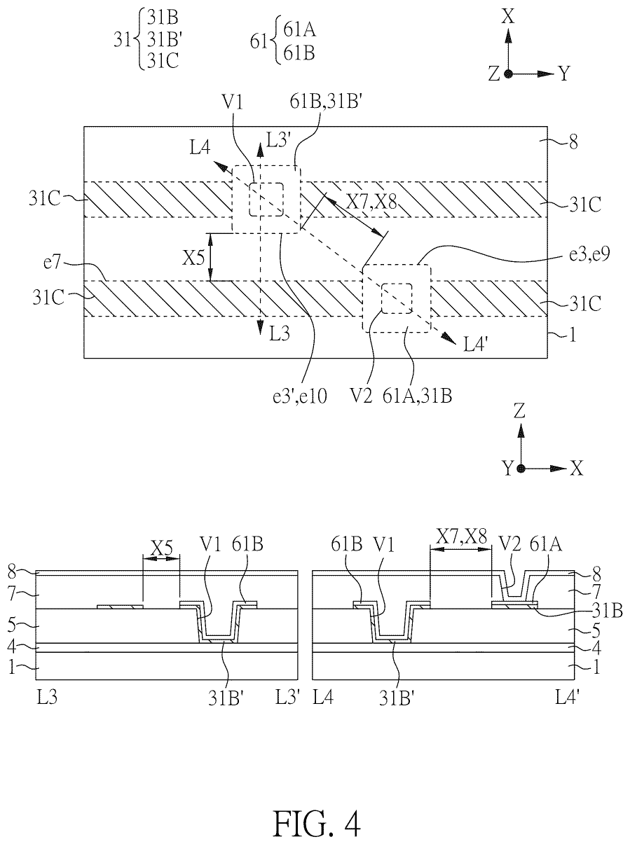

FIG. 4 is a schematic view showing a part of an electronic device according to one embodiment of the present disclosure. The upper portion of FIG. 4 is a top schematic view, and the lower portion is cross-sectional schematic views of the line L3-L3′ and the line L4-L4′. In addition, the electronic device of FIG. 4 is similar to that shown in FIG. 3F, and the manufacturing method of the electronic device of FIG. 4 is similar to that shown in FIG. 3A to FIG. 3F, except for the following differences.

In one embodiment of the present disclosure, as shown in FIG. 4, the electronic device may not be disposed with the first conductive layer 2. Thus, the electronic device shown in FIG. 4 may not comprise the first conductive pattern 21 (as shown in FIG. 3F). In addition, the mask 61 may comprise a first sub-mask 61A and a second sub-mask 61B. By using the first sub-mask 61A and the second sub-mask 61B together as a mask, the second conductive layer 3 can be patterned to form the second conductive pattern 31. Herein, in the top view direction Z of the substrate 1, the regions of the second conductive pattern 31 overlapped with the first sub-mask 61A and the second sub-mask 61B are the second sub-patterns 31B, 31B′, the region of the second conductive pattern 31 outside the second sub-patterns 31B, 31B′ is the third sub-pattern 31C. In one embodiment of the present disclosure, in the top view direction Z of the substrate 1, a part of the first sub-mask 61A and the second via V2 are overlapped, and a part of the second sub-mask 61B and the first via V1 are overlapped. In one embodiment of the present disclosure, as shown in FIG. 4, the second via V2 may expose a part of the first sub-mask 61A, but the present disclosure is not limited thereto.

In one embodiment of the present disclosure, by using plural sub-masks (for example, the first sub-mask 61A and the second sub-mask 61B) to pattern the second conductive layer 3, plural second sub-patterns 31B, 31B′ may be formed. In the top view direction Z of the substrate 1, one of the plural second sub-patterns (for example, the second sub-pattern 31B′) and the first via V1 of the first insulating layer 5 are overlapped, and the other one of the plural second sub-patterns (for example, the second sub-pattern 31B) and the second via V2 of the second insulating layer 7 are overlapped. In one embodiment of the present disclosure, the distance X8 between adjacent second sub-patterns 31B, 31B′ may be approximately equal to the distance X7 between the first sub-mask 61A and the second sub-mask 61B. In one embodiment of the present disclosure, the distance X5 between the third sub-pattern 31C and the second sub-pattern 31B′ may be less than the distance X8 between adjacent second sub-patterns 31B, 31B′. The “distance X8” refers to, for example, the shortest straight line distance between the edge e3 of the second sub-pattern 31B and the edge e3′ of the adjacent second sub-pattern 31B′ observed from the top view direction Z of the substrate 1. The “distance X5” refers to, for example, the shortest straight line distance from the edge e7 of the third sub-pattern 31C adjacent to and not connected to one of the plural second sub-patterns 31B, 31B′ (for example, the second sub-pattern 31B′) to the edge e3′ of the one of the plural second sub-patterns (for example, the second sub-pattern 31B′) when observed from the top view direction Z of the substrate 1. The “distance X7” refers to, for example, the shortest straight line distance between the edge e9 of the first sub-mask 61A to the edge e10 of the second sub-mask 61B observing from the top view direction Z of the substrate 1.

In the present disclosure, the detailed features, materials and preparation methods of each component in the electronic device are as described above and will not be described again here.

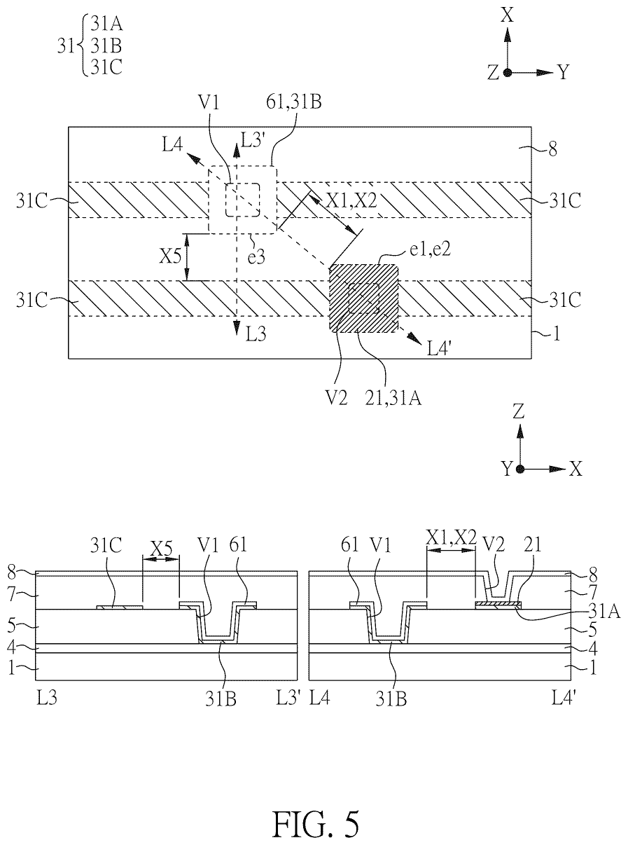

FIG. 5 is a schematic view showing a part of an electronic device according to one embodiment of the present disclosure. The upper portion of FIG. 5 is a top schematic view, and the lower portion is cross-sectional schematic views of the line L3-L3′ and the line L4-L4′. In addition, the electronic device of FIG. 5 is similar to that shown in FIG. 3F, and the manufacturing method of the electronic device of FIG. 5 is similar to that shown in FIG. 3A to FIG. 3F, except for the following differences.

In one embodiment of the present disclosure, as shown in FIG. 5, the first conductive pattern 21 may be disposed on the first sub-pattern 31A. Thus, the method for manufacturing the electronic device may comprise: forming the second conductive layer 3 (as shown in FIG. 3B) on the substrate 1, and then forming the first conductive pattern 21 and the mask 61 on the second conductive layer 3 (as shown in FIG. 3B). Next, the first conductive pattern 21, the mask 61 and the patterned photoresist (not shown in the figure) are used as a mask to pattern the second conductive layer 3 (as shown in FIG. 3B) to form the second conductive pattern 31. Herein, in the top view direction Z of the substrate 1, the region of the second conductive pattern 31 overlapped with the first conductive pattern 21 is the first sub-pattern 31A, and the region overlapped with the mask 61 is the second sub-pattern 31B. In one embodiment of the present disclosure, in the top view direction Z of the substrate 1, a part of the mask 61 and the first via V1 are overlapped, and a part of the first conductive pattern 21 and the second via V2 are overlapped. In one embodiment of the present disclosure, as shown in FIG. 5, the second via V2 may expose a part of the first conductive pattern 21, but the present disclosure is not limited thereto. In another embodiment of the present disclosure, even not shown in the figure, the second via V2 may expose a part of the first conductive pattern 21 and a part of the first sub-pattern 31A at the same time, but the present disclosure is not limited thereto.

In one embodiment of the present disclosure, the distance X1 between the first sub-pattern 31A and the second sub-pattern 31B may be approximately equal to the distance X2 between the first conductive pattern 21 and the second sub-pattern 31B. The “distance X2” refers to, for example, the shortest straight line distance between the edge e1 of the first conductive pattern 21 and the edge e3 of the second sub-pattern 31B observing from the top view direction Z of the substrate 1. The “distance X1” refers to, for example, the shortest straight line distance between the edge e2 of the first sub-pattern 31A and the edge e3 of the second sub-pattern 31B along the extension direction of the distance X2 when observed from the top view direction Z of the substrate 1.

In the present disclosure, the detailed features, materials and preparation methods of each component in the electronic device are as described above and will not be described again here.

In the present disclosure, since the same etching substance has the etching selectivity for the second conductive layer 3 and the first conductive layer 2 (or the mask 61), the first conductive pattern 21 and/or the mask 61 and the photoresist may be selectively used together as a mask to pattern the second conductive layer 3. Thus, the effect of reducing the line width or increasing the component density can be achieved.

The above specific embodiments are to be construed as illustrative only and not in any way limiting of the remainder of the disclosure.

Although the present disclosure has been explained in relation to its embodiment, it is to be understood that many other possible modifications and variations can be made without departing from the spirit and scope of the disclosure as hereinafter claimed.

1. A method for manufacturing an electronic device, comprising the following steps:
providing a substrate;
forming a first conductive layer on the substrate;
patterning the first conductive layer to form a first conductive pattern;
forming a second conductive layer on the first conductive pattern; and
patterning the second conductive layer to form a second conductive pattern, wherein the second conductive pattern comprises a first sub-pattern and a second sub-pattern, and the first sub-pattern is disposed on the first conductive pattern,
wherein a distance between the first conductive pattern and the second sub-pattern is less than a distance between the first sub-pattern and the second sub-pattern.

2. The method of claim 1, further comprising the following steps before the step of patterning the second conductive layer:
forming an etching barrier layer on the second conductive layer; and
patterning the etching barrier layer to form a mask,
wherein the mask and a portion of the second conductive layer are overlapped in a top view direction of the substrate.

3. The method of claim 2, wherein the second conductive pattern further comprises a third sub-pattern adjacent to the second sub-pattern after the step of patterning the second conductive layer, wherein the second sub-pattern corresponds to the portion of the second conductive layer.

4. The method of claim 3, wherein a distance between the third sub-pattern and the second sub-pattern is less than the distance between the first sub-pattern and the second sub-pattern.

5. The method of claim 1, wherein the same etching substance has etching selectivity for the first conductive layer and the second conductive layer.

6. The method of claim 1, wherein a material of the first conductive layer comprises indium tin oxide (ITO), molybdenum, molybdenum nitride (MoN), tungsten-molybdenum alloy (MoW), tungsten or a combination thereof.

7. The method of claim 1, wherein a material of the second conductive layer comprises titanium nitride (TiN), titanium aluminum alloy (TiAl), titanium aluminum nitride (TiAlN), titanium aluminum oxide (TiAlO), titanium silicon aluminum (TiSiAl), titanium tungsten alloy (TiW), titanium tungsten nitride (TiWN), aluminum nitride (AlNx) or a combination thereof.

8. The method of claim 1, further comprising the following steps before the step of patterning the second conductive layer:
forming a photoresist layer on the second conductive layer; and
patterning the photoresist layer to form a patterned photoresist,
wherein the patterned photoresist and the second conductive pattern are overlapped in the top view direction of the substrate after the step of patterning the second conductive layer.

9. The method of claim 8, wherein the patterned photoresist comprises a first sub-photoresist pattern and a second sub-photoresist pattern, wherein in the top view direction of the substrate, the first sub-photoresist pattern and the first sub-pattern are overlapped, and the second sub-photoresist pattern and the second sub-pattern are overlapped.

10. The method of claim 9, wherein a distance between the first conductive pattern and the second sub-pattern is less than a distance between the first sub-photoresist pattern and the second sub-photoresist pattern.

11. The method of claim 1, wherein the step of patterning the first conductive layer further includes a step of etching the first conductive layer with a first etching substance, and the step of patterning the second conductive layer further includes a step of etching the second conductive layer with a second etching substance, wherein the second etching substance has etching selectivity for the first conductive layer and the second conductive layer.

12. The method of claim 11, wherein the first etching substance is different from the second etching substance.

13. The method of claim 11, wherein the first etching substance comprises oxalic acid (H₂C₂O₄), nitric acid (HNO₃) or a combination thereof.

14. The method of claim 11, wherein the second etching substance comprises sulfur hexafluoride (SF₆), carbon tetrafluoride (CF₄), boron trichloride (BCl₃), chlorine (Cl₂) or a combination thereof.

15. An electronic device, comprising:
a substrate;
a first conductive pattern disposed on the substrate; and
a second conductive pattern comprising a first sub-pattern and a second sub-pattern, wherein the first sub-pattern is disposed on the first conductive pattern, and the second sub-pattern is disposed on the substrate,
wherein a distance between the first conductive pattern and the second sub-pattern is less than a distance between the first sub-pattern and the second sub-pattern.

16. The electronic device of claim 15, wherein the second conductive pattern further comprises a third sub-pattern, and a distance between the third sub-pattern and the second sub-pattern is less than the distance between the first sub-pattern and the second sub-pattern.

17. The electronic device of claim 16, further comprising a mask disposed on the second sub-pattern.

18. The electronic device of claim 16, wherein the third sub-pattern is adjacent to the second sub-pattern.

19. The electronic device of claim 15, wherein a material of the first conductive layer comprises indium tin oxide (ITO), molybdenum, molybdenum nitride (MoN), tungsten-molybdenum alloy (MoW), tungsten or a combination thereof.

20. The electronic device of claim 15, wherein a material of the second conductive pattern comprises titanium nitride (TiN), titanium aluminum alloy (TiAl), titanium aluminum nitride (TiAlN), titanium aluminum oxide (TiAlO), titanium silicon aluminum (TiSiAl), titanium tungsten alloy (TiW), titanium tungsten nitride (TiWN), aluminum nitride (AlNx) or a combination thereof.
